(19) United States
(12) Patent Application Publication
(10) Pub. No.: US 2008/0030231 A1
(43) Pub. Date: Feb. 7, 2008

(54) Level Shifter and Voltage Converting Device

(75) Inventor: Kazuyuki Hashimoto, Kohnan (JP)

Correspondence Address: BIRCH STEWART KOLASCH & BIRCH, PO BOX 747, FALLS CHURCH, VA, 22040-0747, US

(73) Assignee: TOP HONG KONG HOLDING LIMITED, Shatin, Hong Kong (CN)

(21) Appl. No.: 11/661,348

(22) PCT Filed: Aug. 31, 2005
(86) PCT No.: PCT/IB05/52843

§ 371 Date: Feb. 28, 2007

(30) Foreign Application Priority Data
Sep. 3, 2004 (JP) 2004-257675

(51) Int. Cl. H03K 19/0185

(52) U.S. Cl. 326/80

(57) ABSTRACT

A level shifter voltage contributing to a simplified interface and realizing a reduced power consumption and a voltage supplying device using such a level shifter are provided. A level shifter (1) receives an input data (Din) having a voltage of 0V (zero) and a clock signal (CLK) to shift said voltage of 0V to 5V. The level shifter (1) comprises a first means for supplying a voltage of Vdd(=5V) to a node (N1) and a second means for supplying a voltage of Vss(=0V) to the node (N1). The second means operates so as to block a supply of the voltage of Vss to the node (N1) when the first means supplies the voltage of Vdd to the node (N1).

### TECHNICAL FIELD

The invention relates to a level shifter for shifting a first voltage to a second voltage, and a voltage converting device using the level shifter.

### BACKGROUND ART

A display device such as a mobile phone comprises, for example, an IC chip for outputting image data and transistors (e.g. TFT), each of the transistors being formed on glass substrate at respective one of pixels. Each pixel is supplied through respective one of the transistors with a voltage on the basis of the image data outputted from the IC chip. The power supply voltage required for the IC chip is usually different from the power supply voltage required on the glass substrate, so that a level shifter is provided in the IC chip or on the glass substrate.

FIG. 1 is one example of a voltage converting device 100 using the known level shifter.

The voltage converting device 100 comprises a level shifter 101 and a latch 102. The level shifter 101 shifts a voltage level of an input data Din. In order to shift the voltage level of the input data Din, the level shifter requires not only the input data Din but also an inverted input data Din_inv having voltage levels inverted with respect to the voltage levels of the input data Din. Therefore, for example, if the input data Din and the inverted input data Din_inv are supplied from an IC chip to the level shifter 101, the IC chip requires not only an output terminal for the input data Din but also an output terminal for the inverted input data Din_inv. If a display device requires only one level shifter 101, the IC chip requires one pair of the output terminals for the input data Din and the inverted input data Din_inv. However, if the display device processes e.g. multiple bits of data in parallel, a plurality of level shifters 101 are required, so that the IC chip requires a plurality of pairs of an output terminal of the input data Din and an output terminal of the inverted input data Din_inv. Therefore, an interface for connecting the IC chip to the level shifters is complicated.

In addition to the level shifter shown in FIG. 1, level shifters described in e.g. US2002/0118040A1 and U.S. Pat. No. 6,650,167B1 are known.

Unlike the level shifter 101 shown in FIG. 1, the level shifter described in US2002/0118040A1 and U.S. Pat. No. 6,650,167B1 can shift an input voltage level without the inverted input data and thus have an advantage that no inverted input data line is required. However, in the case of these level shifters, a DC current flows from a supply portion of a voltage Vdd to a supply portion of a voltage Vss while these level shifters shift the voltage level, so that a problem of increased power consumption arises.

### DISCLOSURE OF INVENTION

### Technical Problem

It is an object of the invention to provide a level shifter contributing to a simplified interface and realizing reduced power consumption, and provide a voltage supplying device using such level shifter.

### Technical Solution

A level shifter according to the present invention for achieving the object described above receives a first clock signal and data having a first voltage to shift said first voltage to a second voltage, said level shifter comprises a first voltage supplying means for supplying said second voltage to a predetermined position and a second voltage supplying means for supplying a third voltage to said predetermined position, and said second voltage supplying means operates so as to block supply of said third voltage to said predetermined position when said first voltage supplying means supplies said second voltage to said predetermined position.

In the level shifter according to the present invention, said second voltage supplying means operates so as to block supply of said third voltage to said pre-determined position when said first voltage supplying means supplies said second voltage to said predetermined position. Therefore, it can be prevented that current flows between the first and second voltage supplying means when the first voltage supplying means supplies the second voltage to the predetermined position, so that the lower power consumption can be achieved.

The level shifter according to the present invention shifts the first voltage to the second voltage using the first clock signal. If a plurality of level shifters each of which is the level shifter according to the invention are required, the first clock signal can be commonly used for the plurality of level shifters. Therefore, complication of an interface can be reduced, as compared with the prior art in which a plurality of inverted data for a plurality of prior art level shifters are required.

The level shifter according to the invention may be structured in such a way that, during a first period, said first voltage supplying means supplies said second voltage to said predetermined position and said second voltage supplying means blocks supply of said third voltage to said predetermined position, and that, during a second period succeeding to said first period, said first voltage supplying means blocks supply of said second voltage to said predetermined position and said second voltage supplying means continues to block supply of said third voltage to said predetermined position. In this case, such voltage supply and such block of voltage supply may be carried out by a response of the first voltage supplying means to the first clock signal and a response of the second voltage supplying means to the first clock signal and the data.

With such structure, the second voltage supplied to the predetermined position during the first period can be held during the second period. This makes it possible that a level of the first voltage of data is shifted to the second voltage during the second period.

The level shifter according to the invention may be structured in such a way that, during a first period, said first voltage supplying means blocks supply of said second voltage to said predetermined position and said second voltage supplying means supplies said third voltage to said predetermined position, and that during a second period succeeding to said first period, said first voltage supplying means supplies said second voltage to said predetermined position and said second voltage supplying means blocks supply of said third voltage to said predetermined position. In this case, such voltage supply and such block of voltage supply may be carried out by a response of the first voltage supplying means to the first clock signal and a response of the second voltage supplying means to the first clock signal and the data.

With such structure, after the third voltage is supplied to the predetermined position during the first period, the second voltage instead of the third voltage is supplied to the predetermined position during the second period. This makes it possible that a level of the first voltage of data is shifted to the second voltage during the second period.

The level shifter according to the invention may be structured in such a way that said first voltage supplying means comprises a first switch means, said first switch means becoming on-state and off-state in response to said first clock signal, that said second voltage supplying means comprises a second switch means, said second switch means becoming on-state and off-state in response to said first clock signal, and that said second switch means is off-state when said first switch means is on-state and said second switch means is on-state when said first switch means is off-state.

If said second switch means is off-state when said first switch means is on-state and said second switch means is on-state when said first switch means is off-state, it is prevented that current flows between the first and the second voltage supplying means, so that low power consumption is achieved.

The level shifter according to the invention may be structured in such a way that said level shifter comprises a third switch means between said predetermined position and said second switch means, and that said third switch means becoming on-state and off-state in response to said data.

By providing such third switch means, the voltage on the predetermined position during the second period can be made the second voltage, so that a level of the first voltage of the data can be shifted to the second voltage during the second period.

The level shifter according to the invention may be structured in such a way that said first voltage supplying means comprises a fourth switch means, said fourth switch means becoming on-state and off-state in response to said first clock signal, that said second voltage supplying means comprises a data processing means for processing said data and a fifth switch means, said fifth switch means becoming on-state and off-state in response to said processed data, and that said fifth switch means is in off-state when said fourth switch means is in on-state and said fifth switch means is in on-state when said fourth switch means is in off-state. In this case, the level shifter according to the invention may be structured in such a way that the data has a data valid period and a data invalid period and that said data processing means changes a voltage of said data of said data in valid period to a voltage used for making said fifth switch means on-state or off-state.

The data processing means may be structured so as to change a voltage of said data of said data in valid period to a voltage used for making said fifth switch means on-state or off-state by using second clock signal which has voltage levels in versed with respect to voltage levels of said first clock signal. If a plurality of level shifters each of which is the level shifter according to the present invention are required, the second clock signal can be commonly used for the plurality of level shifters. Therefore, complication of an interface can be reduced, as compared with the prior art in which a plurality of inverted data for a plurality of prior art level shifters are required.

### DESCRIPTION OF DRAWINGS

FIG. 1 is one example of the voltage converting device 10 in which the known level shifter is used.

FIG. 2 shows a level shifter 1 of first embodiment according to the present invention.

FIG. 3 is a timing chart of the level shifter 1 shown in FIG. 2.

FIG. 4 shows a level shifter 11 of the second embodiment according to the present invention.

FIG. 5 is a timing chart of the level shifter 11 shown in FIG. 4

FIG. 6 shows a level shifter 10 of the third embodiment according to the present invention.

FIG. 7 is a timing chart of the level shifter 10 shown in FIG. 6.

FIG. 8 is a schematic diagram showing a voltage converting device 50 in which the level shifter 1 shown in FIG. 2 is used.

FIG. 9 shows a timing chart of the voltage converting device 50.

FIG. 10 is schematic diagram showing a voltage converting device 60 of a different example from the voltage converting device 50 shown in FIG. 8.

FIG. 11 is a timing chart of the voltage converting device 60.

FIG. 12 shows an example in which the voltage converting device 50 shown in FIG. 8 is applied to a mobile phone 200.

FIG. 13 shows an example in which a mobile phone 201 comprises a plurality of voltage converting devices 50 and each of the voltage converting devices 50 is the voltage converting device 50 shown in FIG. 8.

FIG. 14 shows an example in which the level shifter 10 shown in FIG. 6 is applied to a mobile phone 300.

FIG. 15 shows an example in which a mobile phone 301 comprises a plurality of voltage converting devices and each of the voltage converting devices is the voltage converting device 82 shown in FIG. 14.

### BEST MODE

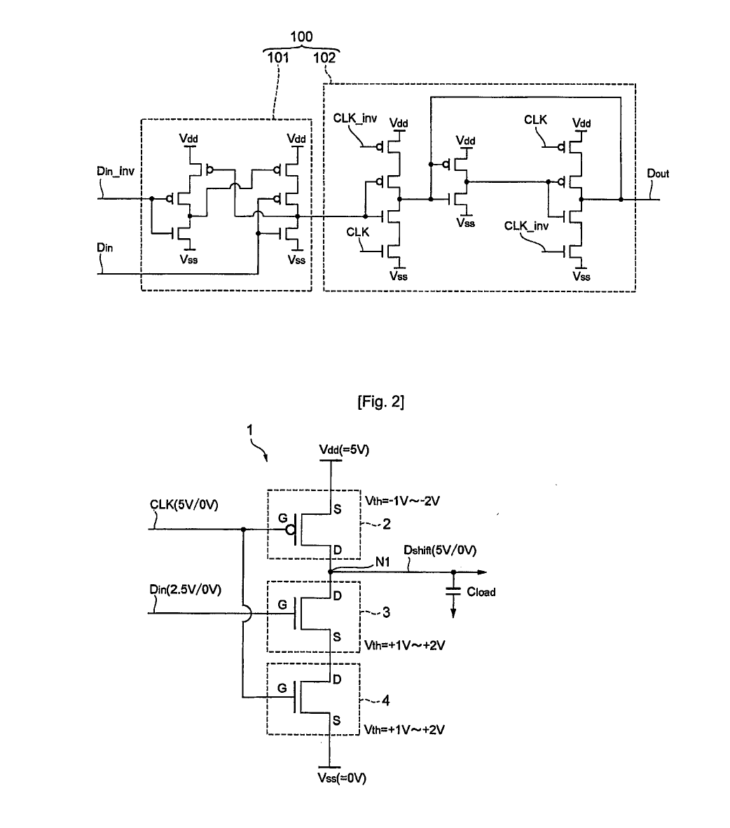

FIG. 2 shows a level shifter 1 of first embodiment according to the present invention.

The level shifter 1 receives a digital signal of 1 bit as an input data Din, and the digital signal is represented by voltage levels of e.g. 0V and 2.5V. The level shifter 1 shifts the voltage level 0V of the input data Din to 5V and shifts the voltage level 2.5V of the input data Din to 0V, and outputs the shifted input data Din as a level shift data Dshift. In order to shift the voltage level as described above, the level shifter 1 comprises one p-type transistor 2 and two n-type transistors 3 and 4. The p-type transistor 2 has a threshold voltage Vth of −1V to −2V and the n-type transistors 3 and 4 have threshold voltages Vth of +1V to +2V. The transistors 2, 3, and 4 are connected in series. A source S of the transistor 2 is connected to a power supply Vdd and a source S of the transistor 4 is connected to a power supply Vss. The power supplies Vdd and Vss supply 5V and 0V, respectively, but may supply different voltages as needed. A node N1 between the transistors 2 and 3 is connected to load capacitance Cload. The load capacitance Cload hypothetically represents input capacitance of a circuit (not shown) receiving the level shift data Dshift. It is noted that, in the level shifter 1 structured as described above, ON/OFF of the transistor 3 is controlled using the input data Din, but ON/OFF of the further transistors 2 and 4 is controlled using a clock signal CLK instead of the input data Din.

The level shifter 1 mainly has two features.

A first feature is that the clock signal CLK is used in order to carry out a level shift. A second feature is that the transistor 2 is the p-type but the transistor 4 is the n-type, and the transistors 2 and 4 are controlled by the clock signal CLK, so that if one of the transistors 2 and 4 is on-state, the other is off-state.

In the following, operation of the level shifter 1 will be described, and next, advantages obtained by providing the level shifter 1 with the features described above will be described.

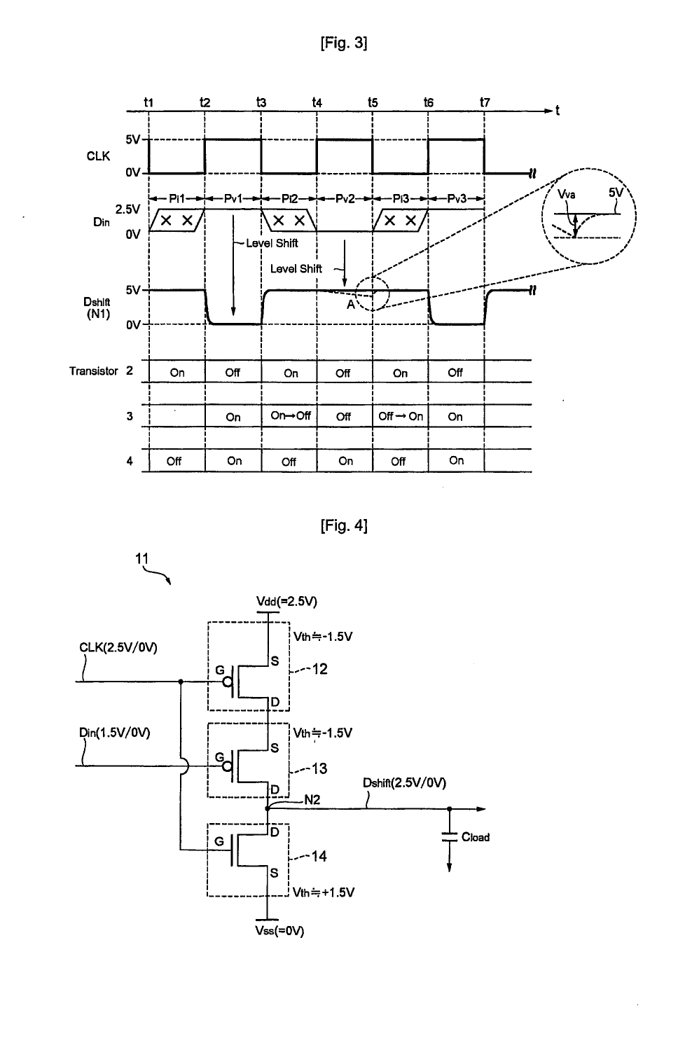

FIG. 3 is a timing chart of the level shifter 1 shown in FIG. 2.

The input data Din received by the level shifter 1 comprises data valid periods Pv1, Pv2, Pv3, . . . and data invalid periods Pi1, Pi2, Pi3, . . . The data valid period and the data invalid period alternate. The data valid period is a period during which a voltage to be shifted is present, so that the voltage of the data valid period is an object to be shifted. On the other hand, the data invalid period is a period during which a voltage level of a data valid period is changed to a voltage level of the next data valid period, and the voltage of the data invalid period is not an object to be shifted. The clock signal CLK received by the level shifter 1 has a high level voltage (5V) during the data valid periods Pv1, Pv2, Pv3, . . . and has a low level voltage (0V) during the data invalid periods Pi1, Pi2, Pi3, . . . In FIG. 3, the clock signal CLK has a duty ratio of 50:50, so that a ratio of a length of the data valid period to a length of the data invalid period is defined as 50:50 accordingly, but these ratios are not limited to 50:50. If the clock signal CLK has not the duty ratio of 50:50 but has the duty ratio of e.g. 60:40, the ratio of the length of the data valid period to the length of the data invalid period is defined as 60:40.

Basic operation of the level shifter 1 is as follows. That is, the level shifter 1 operates during the data invalid period so as to pre-charge the node N1 to the voltage Vdd (=5V), and then operates during the next data valid period so as to hold the voltage Vdd on the pre-charged node N1 or so as to discharge the node N1 from the voltage Vdd (=5V) to the Vss (=0V) on the basis of the voltage level of the input data Din. For example, as shown in FIG. 3, the level shifter 1 pre-charges the node N1 to the voltage Vdd (=5V) during the data invalid period Pi1 and then discharges the node N1 from the voltage Vdd (=5V) to the Vss (=0V) during the next data valid period Pv1. And, the level shifter 1 pre-charges the node N1 to the voltage Vdd (=5V) during the data invalid period Pi2 and then holds the voltage Vdd (=5V) on the node N1 during the next data valid period Pv2. In such a manner, the level shifter 1 shifts the voltage 0V of the input data Din to 5V and shifts the voltage 5V of the input data Din to 0V and then outputs the level shift data Dshift.

Operation when the level shifter 1 outputs the level shift data Dshift will be in detail described below with respect to FIGS. 2 and 3.

During a period from an instant t1 to an instant t2, the clock signal CLK has the low level voltage (=0V), so that the voltage of 0V is applied to the gates G of the p-type and n-type transistors 2 and 4. Therefore, with regard to p-type transistor 2, a voltage V_{GS} between source S and gate G viewed from the source S is as follows.

$$\begin{matrix}{V}_{GS} = {V}_{G} ( = a voltage on the gate G ) - \\ {V}_{S} ( = a voltage on the source S ) \\ = 0 V - Vdd \\ = - 5 V\end{matrix}$$

In this case, since the voltage V_{GS} (=−5V) is smaller than the threshold voltage Vth (=−1V to −2V) of the p-type transistor 2, the p-type transistor 2 becomes on-state.

On the other hand, with regard to the n-type transistor 4, a voltage V_{GS} between source S and gate G viewed from the source S is as follows.

$$\begin{matrix}{V}_{GS} = {V}_{G} ( = a voltage on the gate G ) - \\ {V}_{S} ( = a voltage on the source S ) \\ = 0 V - Vss \\ = 0 V\end{matrix}$$

In this case, since the voltage V_{GS} (=0V) is smaller than the threshold voltage Vth (+1V to +2V) of the n-type transistor 4, the n-type transistor 4 becomes off-state.

Therefore, the transistors 2 and 4 are in the on-state and the off-state, respectively, during the period from the instant t1 to the instant t2 (data invalid period Pi1). The node N1 is connected to the power supply Vdd (=5V) since the transistor 2 is ON, but is not connected to the power supply Vss (=0V) irrespective of whether the transistor 3 is ON or OFF since the transistor 4 is OFF. Therefore, the node N1 is pre-charged to the voltage Vdd (=5V) during the period from the instant t1 to the instant t2 (the data invalid period Pi1), so that the voltage of the level shift data Dshift is set to 5V.

The node N1 is pre-charged to 5V during the data invalid period Pi1 in this way, and then a transition is made to a data valid period Pv1 (the instant t2 to the instant t3).

Since the clock signal CLK has the high level voltage (=5V) during the period from the instant t2 to the instant t3, the voltage of 5V is applied to the gates G of the p-type and n-type transistors 2 and 4. Therefore, with regard to p-type transistor 2, the voltage V_{GS} between source S and gate G viewed from the source S is as follows.

$$\begin{matrix}{V}_{GS} = {V}_{G} ( = a voltage on the gate G ) - \\ {V}_{S} ( = a voltage on the source S ) \\ = 5 V - Vdd \\ = 0 V\end{matrix}$$

In this case, since the voltage V_{GS} (=0V) is larger than the threshold voltage Vth (=−1V to −2V) of the p-type transistor 2, the p-type transistor 2 becomes off-state.

On the other hand, with regard to n-type transistor 4, the voltage V_{GS} between source S and gate G viewed from the source S is as follows.

$$\begin{matrix}{V}_{GS} = {V}_{G} ( = a voltage on the gate G ) - \\ {V}_{S} ( = a voltage on the source S ) \\ = 5 V - Vss \\ = 5 V\end{matrix}$$

In this case, since the voltage V_{GS} (=5V) is larger than the threshold voltage Vth (=+1V to +2V) of the n-type transistor 4, the n-type transistor 4 becomes on-state.

Since the input data Din is 2.5V during the period from the instant t2 to the instant t3 (the data valid period Pv1), the voltage of 2.5V is applied to the gate G of the n-type transistor 3. The voltage Vs on the source S of the n-type transistor 3 is 0V since the n-type transistor 4 is in the on-state. Therefore, with regard to n-type transistor 3, a voltage V_{GS} between source S and gate G viewed from the source S is as follows.

$$\begin{matrix}{V}_{GS} = {V}_{G} ( = a voltage on the gate G ) - \\ {V}_{S} ( = a voltage on the source S ) \\ = 2.5 V - Vss \\ = 2. 5 V\end{matrix}$$

In this case, since the voltage V_{GS} (=2.5V) is larger than the threshold voltage Vth (=+1V to +2V) of the n-type transistor 3, the n-type transistor 3 becomes on-state.

Therefore, during the period from the instant t2 to the instant t3, the node N1 is not connected to the power supply Vdd (=5V) since the transistor 2 is in the off-state, but is connected to the power supply Vss (=0V) since the transistors 3 and 4 are in the on-states. As a result of this, the node N1 is discharged from 5V to 0V at the instant t2, so that the voltage of the level shift data Dshift becomes 0V (the instant t2 to the instant t3).

In this way, the voltage level of the input data Din during the data valid period Pv1 (the instant t2 to the instant t3) is shifted from 2.5V to 0V.

Next, during a period from the instant t3 to the instant t4 (the data invalid period Pi2), the clock signal CLK has the low level voltage (=0V), so that the voltage of 0V is applied to the gates G of the p-type and n-type transistors 2 and 4. Therefore, with regard to p-type transistor 2, the voltage V_{GS} between source S and gate G viewed from the source S is as follows.

$$\begin{matrix}{V}_{GS} = {V}_{G} - {V}_{S} \\ = 0 V - Vdd \\ = - 5 V\end{matrix}$$

In this case, since the voltage V_{GS} (=−5V) is smaller than the threshold voltage Vth (=−1V to −2V) of the p-type transistor 2, the p-type transistor 2 becomes on-state.

On the other hand, with regard to n-type transistor 4, the voltage V_{GS} between source S and gate G viewed from the source S is as follows.

$$\begin{matrix}{V}_{GS} = {V}_{G} - {V}_{S} \\ = 0 V - Vss \\ = 0 V\end{matrix}$$

In this case, since the voltage V_{GS} (=0V) is smaller than the threshold voltage Vth (=+1V to +2V) of the n-type transistor 4, the n-type transistor 4 becomes off-state.

Therefore, the transistors 2 and 4 are in on-state and off-state, respectively, during the period from the instant t3 to the instant t4. The node N1 is connected to the power supply Vdd (=5V) since the transistor 2 is ON, but is not connected to the power supply Vss (=0V) irrespective of whether the transistor 3 is ON or OFF since the transistor 4 is OFF. Therefore, the node N1 is pre-charged to the voltage Vdd (=5V) during the period from the instant t3 to the instant t4 (the data invalid period Pi2), so that the voltage of the level shift data Dshift is set to 5V.

The node N1 is pre-charged to 5V during the data invalid period Pi2 in this way, and then a transition is made to a data valid period Pv2 (the instant t4 to the instant t5).

During the period from the instant t4 to the instant t5, the clock signal CLK has the high level voltage (=5V), so that the transistors 2 and 4 are in the off-state and on-state, respectively. Since the input data Din is 0V, the voltage of 0V is applied to the gate G of the n-type transistor 3. The voltage on the source S of the n-type transistor 3 is 0V since the n-type transistor 4 is in the on-state. Therefore, with regard to n-type transistor 3, the voltage V_{GS} between source S and gate G viewed from the source S is as follows.

$$\begin{matrix}{V}_{GS} = {V}_{G} - {V}_{S} \\ = 0 V - Vss \\ = 0 V\end{matrix}$$

In this case, since the voltage V_{GS} (=0V) is smaller than the threshold voltage Vth (+1V to +2V) of the n-type transistor 3, the n-type transistor 3 becomes off-state. Therefore, the node N1 is not connected to the power supply Vss. During the data valid period Pv2 (the instant t4 to the instant t5), the node N1 also is not connected to the power supply Vdd (=5V) since the transistor 2 is in the off-state. As a result of this, the node N1 continuously holds 5V of the data invalid period Pi2 (the instant t3 to the instant t4) during the data valid period Pv2 (the instant t4 to the instant t5), so that the voltage of the level shift data Dshift remains 5V.

Therefore, the voltage 0V of the input data Din during the data valid period Pv2 (the instant t4 to the instant t5) is shifted to 5V.

As described above, the node N1 is not connected to the power supplies Vdd and Vss during the instant t4 to the instant t5. Therefore, the voltage on the node N1 may change because of occurrence of a leak current and a change of the load capacitance Cload, so that the voltage of 5V may not be substantially held. Within a region A in FIG. 3, a situation in which the voltage on the node N1 changes and thus the voltage at the instant t5 deviates from the voltage at the instant t4 by Vva is illustrated with a broken line. If such amount of change in voltage Vva can be negligible, no problem occurs. If such amount of change in voltage Vva can not negligible, strategies (1) or (2) described below can take depending on whether the cause of the amount of change in voltage Vva lies mainly in the occurrence of the leak current or the change of the load capacitor Cload.

(1) A case in which the cause of the amount of change in voltage Vva lies mainly in the occurrence of the leak current.

In this case, a manner in which frequencies of the clock signal CLK and the input data Din are increased can be considered for example. This shortens the data valid periods and thus makes it possible that the amount of change in voltage Vva becomes smaller. In another manner, the leak current can become smaller by making size of the transistor 2, 3 or 4 smaller since the smaller size of the transistor 2, 3 or 4 makes resistance of the transistor 2, 3 or 4 higher. Therefore, to make the size of the transistor smaller is one strategy if the frequency of the clock signal can not be increased.

(2) A case in which the cause of the amount of change in voltage Vva lies mainly in the change of the load capacitor Cload.

In this case, a manner in which an inverter is provided between the node N1 and the load capacitor Cload can be considered for example. By this manner, the level shifter 1 can output the level shift data Dshift with the level shifter 1 not being substantially affected by the change of the load capacitor Cload.

If the cause of the amount of change in voltage Vva lies both in the occurrence of the leak current and in the change of the load capacitor Cload, both strategies (1) and (2) described above can be used in combination.

Next, during the period from the instant t5 to the instant t6 (data invalid period Pi3), the clock signal CLK has the low level voltage (=0V), so that the transistors 2 and 4 are in the on-state and off-state, respectively. The node N1 is connected to the power supply Vdd (=5V) since the transistor 2 in ON, but is not connected to the power supply Vss (=0V) irrespective of whether the transistor 3 is ON or OFF since the transistor 4 is OFF. Therefore, the node N1 is pre-charged to the voltage Vdd (=5V) during the period from the instant t5 to the instant t6 (the data invalid period Pi3), so that the voltage of the level shift data Dshift is set to 5V.

Next, a transition is made to a data valid period Pv3 (the instant t6 to the instant t7).

During the period from the instant t6 to the instant t7, the clock signal CLK has the high level voltage (=5V), so that the transistors 2 and 4 are in the off-state and on-state, respectively. During the period from the instant t6 to the instant t7, the input data Din is 2.5V, so that the voltage of 2.5V is applied to the gate G of the n-type transistor 3. The voltage on the source S of the n-type transistor 3 is 0V since the n-type transistor 4 is in the on-state. Therefore, the voltage V_{GS} of the n-type transistor 3 is 2.5V and is lager than the threshold voltage Vth (=+2V). As a result of this, the n-type transistor 3 becomes on-state.

Therefore, during the period from the instant t6 to the instant t7, the transistor 2 is in the off-state, but the transistors 3 and 4 are in the on-state, so that the node N1 is connected to the power supply Vss (=0V). As a result of this, the node N1 is discharged from 5V to 0V at the instant t6, so that the voltage of the level shift data Dshift becomes 0V (the instant t6 to the instant t7). In this way, the voltage 2.5V of the input data Din during the data valid period Pv3 (the instant t6 to the instant t7) is shifted to 0V.

As described above, the level shifter 1 shown in FIG. 2 shifts the voltage 0V of the input data Din to 5V and shifts the voltage 2.5V of the input data Din to 0V and outputs the level-shifted input data Din as the level shift data Dshift.

The level shifter 1 shown in FIG. 2 can output the level shift data Dshift without an inverted input data Din_inv used for shifting a level of the input data Din. In the level shifter 1, the p-type transistor 2 at the side of the voltage Vdd and the n-type transistor 4 at the side of the voltage Vss with respect to the node N1 are controlled by the clock signal CLK, so that if one of these transistors is in the on-state, the other is in the off-state (see FIG. 3). Therefore, during the operation of the level shifter 1, the power supply Vdd and the power supply Vss are prevented from becoming shorted to each other. As a result of this, it is prevented that DC current flows from the power supply Vdd to Vss, so that lower power consumption is achieved.

The clock signal CLK has the voltage levels of 0V and 5V and the input data Din has the voltage levels of 0V and 2.5V in the first embodiment, but it is noted that the voltage levels of the clock signal CLK and the input data Din are not limited to the values described above as long as the level shifter 1 shown in FIG. 2 carries out the level shift operation. The power supply Vdd and the power supply Vss supply the voltages 5V and 0V in the first embodiment, respectively, but it is noted that the power supply Vdd and the power supply Vss are not limited to 5V and 0V, respectively, as long as the level shifter 1 shown in FIG. 2 carries out the level shift operation.

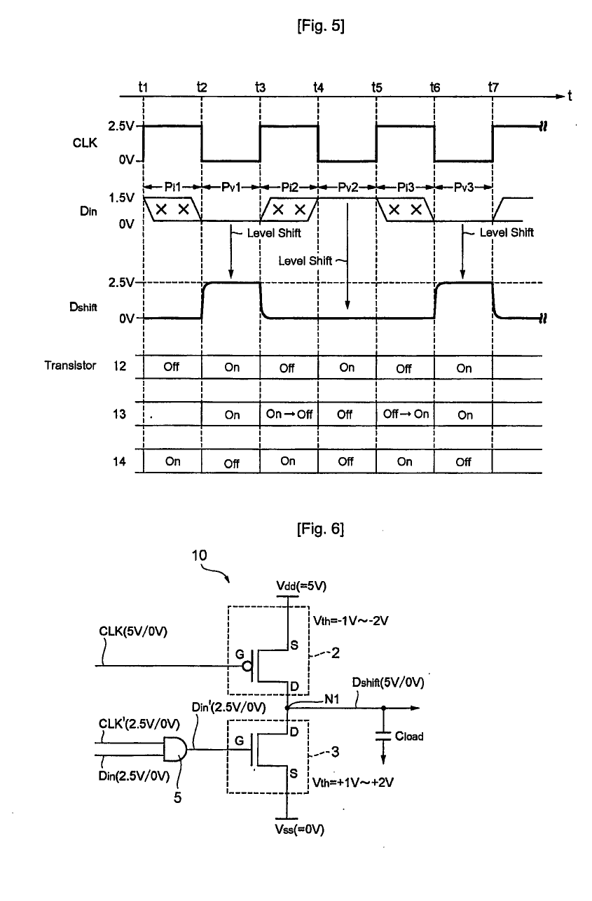

FIG. 4 shows a level shifter 11 of second embodiment according to the present invention.

The level shifter 11 receives a digital signal of 1 bit as an input data Din, and the digital signal is represented by voltage levels of e.g. 0V and 1.5V. The level shifter 11 shifts the voltage level 0V of the input data Din to 2.5V and shifts the voltage level 1.5V of the input data Din to 0V and outputs the shifted input data Din as a level shift data Dshift. In order to shift the voltage level as described above, the level shifter 11 comprises two p-type transistors 12 and 13 and one n-type transistor 14. Each of the transistors 12 and 13 has a threshold voltage Vth of substantially −1.5V and the transistor 14 has a threshold voltage Vth of substantially +1.5V. The transistors 12, 13, and 14 are connected in series. The source S of the transistor 12 is connected to the power supply Vdd (=2.5) and the source S of the transistor 14 is connected to the power supply Vss (=0V). A node N2 between the transistors 13 and 14 is connected to load capacitance Cload.

It is noted that, in the level shifter 11 structured as described above, on-off control of the transistor 13 is carried out using the input data Din, but on-off control of the other transistors 12 and 14 is carried out not using the input data Din but using the clock signal CLK.

Operation of the level shifter 11 is described below.

FIG. 5 is a timing chart of the level shifter 11 shown in FIG. 4.

The input data Din received by the level shifter 11 comprises data valid periods Pv1, Pv2, Pv3, . . . and data invalid periods Pi1, Pi2, Pi3, . . . The data valid period and the data invalid period alternate. The data valid period is a period during which a voltage to be shifted is present, so that the voltage of the data valid period is an object to be shifted. On the other hand, the data invalid period is a period during which a voltage level of a data valid period is changed to a voltage level of the next data valid period, and the voltage of the data invalid period is not an object to be shifted. The clock signal CLK received by the level shifter 11 has a low level voltage (0V) during data valid periods Pv1, Pv2, Pv3, . . . and has a high level voltage (2.5V) during data invalid periods Pi1, Pi2, Pi3, . . .

Basic operation of the level shifter 11 is as follows. That is, the level shifter 11 operates during the data invalid period so as to discharge the node N2 to the voltage Vss (=0V), and then operates during the next data valid period so as to hold the voltage Vss on the discharged node N2 or so as to charge the node N2 from the voltage Vss (=0V) to the Vdd (=5V) on the basis of the voltage level of the input data Din. For example, as shown in FIG. 5, the level shifter 11 discharges the node N2 to the voltage Vss (=0V) during the data invalid period Pi1 and then charges the node N2 from the voltage Vss (=0V) to the Vdd (=2.5V) during the data valid period Pv1. And, the level shifter 11 discharges the node N2 to the voltage Vss (=0V) during the data invalid period Pi2 and then holds the voltage Vss on the node N2 during the next data valid period Pv2. In such a manner, the level shifter 11 shifts the voltage 0V of the input data Din to 2.5V and shifts the voltage 1.5V of the input data Din to 0V and then outputs the level shift data Dshift.

Operation when the level shifter 11 outputs the level shift data Dshift will be in detail described below with respect to FIGS. 4 and 5.

During a period from an instant t1 to an instant t2, the clock signal CLK has the high level voltage (=2.5V), so that the voltage of 2.5V is applied to the gates G of the p-type and n-type transistors 12 and 14. Therefore, with regard to p-type transistor 12, a voltage V_{GS} between source S and gate G viewed from the source S is as follows.

$$\begin{matrix}{V}_{GS} = {V}_{G} ( = a voltage on the gate G ) - \\ {V}_{S} ( = a voltage on the source S ) \\ = 2.5 V - Vdd \\ = 0 V\end{matrix}$$

In this case, since the voltage V_{GS} (=0V) is larger than the threshold voltage Vth (≈−1.5V) of the p-type transistor 12, the p-type transistor 12 becomes off-state.

On the other hand, with regard to n-type transistor 14, a voltage V_{GS} between source S and gate G viewed from the source S is as follows.

$$\begin{matrix}{V}_{GS} = {V}_{G} ( = a voltage on the gate G ) - \\ {V}_{S} ( = a voltage on the source S ) \\ = 2.5 V - Vss \\ = 2.5 V\end{matrix}$$

In this case, since the voltage V_{GS} (=2.5V) is larger than the threshold voltage Vth (≈+1.5V) of the n-type transistor 14, the n-type transistor 14 becomes on-state.

Therefore, the transistors 12 and 14 are in off-state and on-state, respectively, during the period from the instant t1 to the instant t2 (data invalid period Pi1). The node N2 is connected to the power supply Vss (=0V) since the transistor 12 is ON, but is not connected to the power supply Vdd (=2.5V) irrespective of whether the transistor 13 is ON or OFF since the transistor 12 is OFF. Therefore, the node N2 is discharged to the voltage Vss (=0V) during the period from the instant t1 to the instant t2 (the data invalid period Pi1), so that the voltage of the level shift data Dshift is set to 0V.

The node N1 is discharged to 0V during the data invalid period Pi1 in this way, and then a transition is made to a data valid period Pv1 (the instant t2 to the instant t3).

Since the clock signal CLK has the low level voltage (=0V) during the period from the instant t2 to the instant t3, the voltage of 0V is applied to the gates G of the p-type and the n-type transistors 12 and 14. Therefore, with regard to p-type transistor 12, the voltage V_{GS} between source S and gate G viewed from the source S is as follows.

$$\begin{matrix}{V}_{GS} = {V}_{G} ( = a voltage on the gate G ) - {V}_{S} ( = a voltage on the source S ) \\ = 0 V - Vdd \\ = - 2.5 V\end{matrix}$$

In this case, since the voltage V_{GS} (=−2.5V) is smaller than the threshold voltage Vth (≈−1.5V) of the p-type transistor 12, the p-type transistor 12 becomes on-state.

On the other hand, with regard to n-type transistor 14, the voltage V_{GS} between source S and gate G viewed from the source S is as follows.

$$\begin{matrix}{V}_{GS} = {V}_{G} ( = a voltage on the gate G ) - {V}_{S} ( = a voltage on the source S ) \\ = 0 V - Vss \\ = 0 V\end{matrix}$$

In this case, since the voltage V_{GS} (=0V) is smaller than the threshold voltage Vth (≈+1.5V) of the n-type transistor 14, the n-type transistor 14 becomes off-state.

Since the input data Din is 0V during the period from the instant t2 to the instant t3 (the data valid period Pv1), the voltage of 0V is applied to the gate G of the p-type transistor 13. The voltage Vs on the source S of the p-type transistor 13 is Vdd (=2.5V) since the n-type transistor 12 is in the on-state. Therefore, with regard to p-type transistor 13, a voltage V_{GS} between source S and gate G viewed from the source S is as follows.

$$\begin{matrix}{V}_{GS} = {V}_{G} ( = a voltage on the gate G ) - {V}_{S} ( = a voltage on the source S ) \\ = 0 V - Vdd \\ = - 2.5 V\end{matrix}$$

In this case, since the voltage V_{GS} (=−2.5V) is smaller than the threshold voltage Vth (≈=−1.5V) of the p-type transistor 13, the p-type transistor 13 becomes on-state.

Therefore, during the period from the instant t2 to the instant t3, the node N2 is not connected to the power supply Vss (=0V) since the transistor 14 is in the off-state, but is connected to the power supply Vdd (=2.5V) since the transistors 12 and 13 are in the on-states. As a result of this, the node N2 is charged from 0V to 2.5V at the instant t2, so that the voltage of the level shift data Dshift becomes 2.5V (the instant t2 to the instant t3).

In this way, the voltage level of the input data Din during the data valid period Pv1 (the instant t2 to the instant t3) is shifted from 0V to 2.5V.

Next, during a period from the instant t3 to the instant t4 (the data invalid period Pi2), the clock signal CLK has the high level voltage (=2.5V), so that the voltage of 2.5V is applied to the gates G of the p-type and n-type transistors 12 and 14. Therefore, with regard to p-type transistor 12, the voltage V_{GS} between source S and gate G viewed from the source S is as follows.

$$\begin{matrix}{V}_{GS} = {V}_{G} - {V}_{S} \\ = 2.5 V - Vdd \\ = 0 V\end{matrix}$$

In this case, since the voltage V_{GS} (=0V) is larger than the threshold voltage Vth (=−1.5V) of the p-type transistor 12, the p-type transistor 12 becomes off-state.

On the other hand, with regard to n-type transistor 14, the voltage V_{GS} between source S and gate G viewed from the source S is as follows.

$$\begin{matrix}{V}_{GS} = {V}_{G} - {V}_{S} \\ = 2.5 V - Vss \\ = 2.5 V\end{matrix}$$

In this case, since the voltage V_{GS} (=2.5V) is larger than the threshold voltage Vth (≈+1.5V) of the n-type transistor 14, the n-type transistor 14 becomes on-state.

Therefore, the transistors 12 and 14 are in on-state and off-state, respectively, during the period from the instant t3 to the instant t4. The node N2 is connected to the power supply Vss (=0V) since the transistor 14 is ON, but is not connected to the power supply Vdd (=2.5V) irrespective of whether the transistor 13 is ON or OFF since the transistor 12 is OFF. Therefore, the node N2 is discharged to the voltage Vss (=0V) during the period from the instant t3 to the instant t4 (the data invalid period Pi2), so that the voltage of the level shift data Dshift is set to 0V.

The node N2 is discharged to 0V during the data invalid period Pi2 in this way, and then a transition is made to a data valid period Pv2 (the instant t4 to the instant t5).

During the period from the instant t4 to the instant t5, the clock signal CLK has the low level voltage (=0V), so that the transistors 12 and 14 are in the on-state and off-state, respectively. Since the input data Din is 1.5V, the voltage of 1.5V is applied to the gate G of the p-type transistor 13. The voltage on the source S of the p-type transistor 13 is Vdd (=2.5V) since the p-type transistor 12 is in the on-state. Therefore, with regard to p-type transistor 13, the voltage V between source S and gate G viewed from the source S is as follows.

$$\begin{matrix}{V}_{GS} = {V}_{G} - {V}_{S} \\ = 1.5 V - Vdd \\ = - 1 V\end{matrix}$$

In this case, since the voltage V_{GS} (=−1V) is larger than the threshold voltage Vth (−1.5V) of the p-type transistor 13, the p-type transistor 13 becomes off-state. Therefore, the node N2 is not connected to the power supply Vdd (=2.5V). During the data valid period Pv2 (the instant t4 to the instant t5), the node N2 also is not connected to the power supply Vss (=0V) since the transistor 14 is in the off-state. As a result of this, the node N2 continuously holds 0V of the data invalid period Pi2 (the instant t3 to the instant t4) during the data valid period Pv2, so that the voltage of the level shift data Dshift becomes 0V (the instant t4 to the instant t5).

As described above, the node N2 is not connected to the power supplies Vdd and Vss during the instant t4 to the instant t5. Therefore, the voltage on the node N2 may change because of an occurrence of a leak current and a change of the load capacitance Cload, so that the voltage of 0V may not be substantially held. In this case, the same strategies as (1) and/or (2) explained with reference to FIG. 3 can be used.

Next, during the period from the instant t5 to the instant t6 (data invalid period Pi3), the clock signal CLK has the high level voltage (=2.5V), so that the transistors 12 and 14 are in the off-state and on-state, respectively. The node N2 is connected to the power supply Vss (=0V) since the transistor 14 in ON, but is not connected to the power supply Vdd (=2.5V) irrespective of whether the transistor 13 is ON or OFF since the transistor 12 is OFF. Therefore, the node N2 is discharged to the voltage Vss (=0V) during the period from the instant t5 to the instant t6 (the data invalid period Pi3), so that the voltage of the level shift data Dshift is set to 0V.

Next, a transition is made to a data valid period Pv3 (the instant t6 to the instant t7).

During the period from the instant t6 to the instant t7, the clock signal CLK has the low level voltage (=0V), so that the transistors 12 and 14 are in the on-state and off-state, respectively. During the period from the instant t6 to the instant t7, the input data Din is 0V, so that the voltage of 0V is applied to the gate G of the p-type transistor 13. The voltage on the source S of the p-type transistor 13 is 2.5V since the n-type transistor 12 is in the on-state. Therefore, the voltage V_{GS} of the p-type transistor 13 is −2.5V and is smaller than the threshold voltage Vth (≈−1.5V). As a result of this, the p-type transistor 13 becomes on-state.

Therefore, during the period from the instant t6 to the instant t7, the transistor 14 is off-state, but the transistors 12 and 13 are on-state, so that the node N2 is connected to the power supply Vdd(=2.5V). As a result of this, the node N2 is charged from 0V to 2.5V at the instant t6, so that the voltage of the level shift data Dshift becomes 2.5V (the instant t6 to the instant t7).

In this way, the level shifter 11 shown in FIG. 4 shifts the voltage level 0V of the input data Din to 2.5V and shifts the voltage level 1.5V of the input data Din to 0V and outputs the level-shifted input data Din as the level shift data Dshift.

The level shifter 11 shown in FIG. 4 can output the level shift data Dshift without an inverted input data Din_inv used for shifting a level of the input data Din. In the level shifter 11, the p-type transistor 12 at the side of the voltage Vdd and the n-type transistor 14 at the side of the voltage Vss with respect to the node N2 are controlled by the clock signal CLK, so that if one of these transistors is in the on-state, the other is in the off-state (see FIG. 5). Therefore, during the operation of the level shifter 11, the power supply Vdd and the power supply Vss are prevented from becoming shorted to each other. As a result of this, it is prevented that DC current flows from the power supply Vdd to Vss, so that low power consumption is achieved.

It is possible that the input data Din having the voltages 1.5V and 0V is shifted to the level shift data Dshift having the voltages 5V and 0V by combining the level shifters 11 and 1 shown in FIGS. 4 and 2.

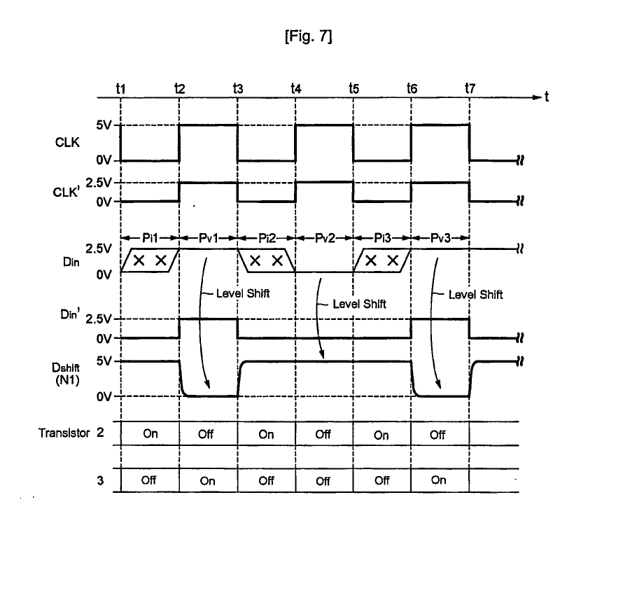

FIG. 6 shows a level shifter 10 of the third embodiment according to the present invention. FIG. 7 is a timing chart of the level shifter 10 shown in FIG. 6.

It is noted that the level shifter 10 shown in FIG. 6 dose not comprise the transistor 4 shown in FIG. 2, but instead comprises an AND circuit 5. The AND circuit 5 receives an input data Din and an clock signal CLK′ and outputs an input data Din into a gate G of the transistor 3. The input data Din′ represents a logical sum of the input data Din and the clock signal CLK′.

In the following, operation of the level shifter 10 will be described using a timing chart of the level shifter 10 (see FIG. 7).

Basic operation of the level shifter 10 is the same as that of the level shifter 1 shown in FIG. 2. That is, the level shifter 10 pre-charges the node N1 to the voltage Vdd (=5V) during the data invalid period. Next, if the voltage of the input data Din during the data valid period is 0V, the voltage Vdd on the pre-charged node N1 is held, and if the voltage of the input data Din is 5V, the node N1 is discharged from the Vdd (=5V) to Vss (=0V). Therefore, the Dshift outputted from the level shifter 10 shown in FIG. 6 is the same as the Dshift outputted from the level shifter 1 shown in FIG. 2 (see timing charts shown in FIGS. 7 and 3). However, the level shifter 10 shown in FIG. 6 shifts level of the input data Din by not only using the first clock signal CLK but also using the second clock signal CLK′. A difference between the clock signals CLK and CLK′ is that the high level voltage of the first clock signal CLK is 5V, while the high level voltage of the second clock signal CLK′ is 2.5V. The second clock signal CLK′ and the input data Din are received by the AND circuit 5.

The AND circuit 5 changes the input data Din to the input data Din′ on the basis on the second clock signal CLK′ and then outputs the input data Din′ (hereinafter, the input data Din′ is referred to as “changed input data Din′”). More specifically, the AND circuit 5 outputs the voltage level of the input data Din when the second clock signal CLK′ is high level voltage (=2.5V), and outputs low level voltage (=0V) as the changed input data Din′ when one of the second clock signal CLK′ and the input data Din is low level voltage (=0V). As shown in the timing chart of FIG. 7, during the data valid periods Pv1, Pv2, . . . , the voltage of the second clock signal CLK′ is high level (=2.5V), so that the AND circuit 5 outputs the voltages of the input data Din of the data valid periods Pv1, Pv2, . . . as the voltages of the changed input data Din′. During the data invalid periods Pi1, Pi2, . . . , the second clock signal CLK′ is low level voltage (=0V), so that the AND circuit 5 outputs voltage of 0V as the changed input data Din′ irrespective of the voltage level of the input data Din of the data invalid periods Pi1, Pi2, . . .

Such changed input data Din′ controls the transistor 3, so that the level shifter 10 operates as follows.

During the period from the instant t1 to the instant t2, the first clock signal CLK has the low level voltage (=0V), so that the voltage of 0V is applied to the gate G of the p-type transistor 2. Therefore, the voltage V_{GS} of the p-type transistor 2 is −5V and thus is smaller than the threshold voltage Vth (=−1V to −2V) of the p-type transistor 2. As a result, the p-type transistor 2 becomes on-state.

Since the second clock signal CLK′ is 0V during the period from the instant t1 to the instant t2, it is noted that the AND circuit 5 outputs the voltage of 0V as the changed input data Din′. Therefore, the voltage V_{GS} of the n-type transistor 3 is 0V and thus is smaller than the threshold voltage Vth (=+1V to +2V) of the n-type transistor 3, so that the n-type transistor 3 becomes off-state.

Since the p-type transistor 2 is in the on-state and the n-type transistor 3 is in the off-state, the node N1 is connected to the power supply Vdd (=5V). Therefore, the node N1 is pre-charged to the voltage Vdd (=5V) during the period from the instant t1 to the instant t2 (the data invalid period Pi1), so that the voltage of the level shift data Dshift is set to 5V.

The node N1 is pre-charged to 5V during the data invalid period Pi1 in this way, and next, a transition is made to the data valid period Pv1 (the instant t2 to the instant t3).

During the period from the instant t2 to the instant t3, the first clock signal CLK is the high level voltage (=5V), so that the voltage of 5V is applied to the gate G of the p-type transistor 2. Therefore, the voltage V_{GS} of the p-type transistor 2 is 0V and thus is larger than the threshold voltage Vth (=−1V to −2V) of the p-type transistor 2. As a result, the p-type transistor 2 becomes off-state.

Further, since the second clock signal CLK′ is 2.5V and the input data Din also is 2.5V during the period from the instant t2 to the instant t3, the AND circuit 5 outputs the voltage of 2.5V as the changed input data Din′, so that the voltage of 2.5V is applied to the gate G of the n-type transistor 3. Therefore, the voltage V_{GS} of the n-type transistor 3 is 2.5V and thus is larger than the threshold voltage Vth (=+1V to +2V) of the n-type transistor 3, so that the n-type transistor 3 becomes on-state.

During the period from the instant t2 to the instant t3, the node N1 is not connected to the power supply Vdd (=5V) since the transistor 2 is in the off-state, but is connected to the power supply Vss (=0V) since the transistor 3 is in the on-state. As a result, the node N1 is discharged from 5V to 0V at the instant t2, so that the voltage of the level shift data Dshift becomes 0V (the instant t2 to the instant t3).

In this way, the voltage level of the input data Din during the data valid period Pv1 (the instant t2 to the instant t3) is shifted from 2.5V to 0V.

Next, during the period from the instant t3 to the instant t4, the first clock signal CLK has the low level voltage (=0V), so that the voltage of 0V is applied to the gate G of the p-type transistor 2. Therefore, the voltage V_{GS} of the p-type transistor 2 is −5V and thus is smaller than the threshold voltage Vth (=−1V to −2V) of the p-type transistor 2. As a result, the p-type transistor 2 becomes on-state.

Since the second clock signal CLK′ is 0V during the period from the instant t3 to the instant t4, it is noted that the AND circuit 5 outputs the voltage of 0V as the changed input data Din′. Therefore, the voltage V_{GS} of the n-type transistor 3 is 0V and thus is smaller than the threshold voltage Vth (=+1V to +2V) of the n-type transistor 3, so that the n-type transistor 3 becomes off-state.

Therefore, the transistors 2 and 3 are in the on-state and off-state, respectively, during the period from the instant t3 to the instant t4. The node N1 is connected to the power supply Vdd (=5V) since the transistor 2 is ON, but is not connected to the power supply Vss (=0V) since the transistor 3 is OFF. Therefore, during the period from the instant t3 to the instant t4 (the data invalid period Pi2), the node N1 is pre-charged to the voltage Vdd (=5V), so that the voltage of the level shift data Dshift is set to 5V.

The node N1 is pre-charged to 5V during the data invalid period Pi2 in this way, and next, a transition is made to the data valid period Pv2 (the instant t4 to the instant t5).

During the period from the instant t4 to the instant t5, the AND circuit 5 outputs the voltage of 0V as the changed input data Din′ since the second clock signal CLK′ is 2.5V and the input data Din is 0V, so that the voltage of 0V is applied to the gate G of the n-type transistor 3. Therefore, the n-type transistor 3 becomes off-state.

During the period from the instant t4 to the instant t5, the first clock signal CLK is the high level voltage (=5V), so that the voltage of 5V is applied to the gate G of the p-type transistor 2. Therefore, the p-type transistor 2 becomes off-state.

Since the transistors 2 and 3 are both off-state as described above, the node N1 is not connected to the power supplies Vdd and Vss. As a result of this, the node N1 continuously holds the voltage 5V of the data invalid period Pi2 (the instant t3 to the instant t4) during the data valid period Pv2 (the instant t4 to the instant t5), so that the voltage of the level shift data Dshift remains 5V. In this way, the voltage 0V of the input data Din during the data valid period Pv2 (the instant t4 to the instant t5) is shifted to 5V.

In a case in which the voltage of 5V on the node N1 changes because of an occurrence of a leak current and a change of the load capacitance Cload and consequently the amount of change in voltage during the data valid period Pv2 can not be negligible, the strategies (1) and/or (2) explained with reference to FIG. 3 can be used.

Next, during the period from the instant t5 to the instant t6, the first clock signal CLK has the low level voltage (=0V) and thus the voltage of 0V is applied to the gate G of the p-type transistor 2, so that the p-type transistor 2 becomes on-state.

Further, since the second clock signal CLK′ is 0V during the period from the instant t5 to the instant t6, the AND circuit 5 outputs the voltage of 0V as the changed input data Din′, so that the n-type transistor 3 becomes off-state.

Since the p-type transistor 2 is in the on-state and the n-type transistor 3 is in the off-state, the node N1 is connected to the power supply Vdd (=5V), so that the voltage of the level shift data Dshift is kept 5V (the instant t5 to the instant t6).

Next, during the period from the instant t6 to the instant t7, the first clock signal CLK is the high level voltage (=5V), so that the transistor 2 becomes off-state. And, since the input data Din is 2.5V during the period from the instant t6 to the instant t7, the AND circuit 5 outputs the voltage of 2.5V as the changed input data Din′, so that the n-type transistor 3 becomes on-state.

During the period from the instant t6 to the instant t7, the transistor 2 is in the off-state but the transistor 3 is in the on-state, so that the node N1 is connected to the power supply Vss (=0V). As a result of this, the node N1 is discharged from 5V to 0V at the instant t6, so that the voltage of the level shift data Dshift becomes 0V (the instant t6 to the instant t7). In this way, the voltage 2.5V of the input data Din during the data valid period Pv3 (the instant t6 to the instant t7) is shifted to 0V.

As described above, the level shifter 1 shown in FIG. 2 shifts the voltage 0V of the input data Din to 5V and shifts the voltage 2.5V of the input data Din to 0V, and outputs the level-shifted input data Din as the level shift data Dshift. Therefore, the Dshift outputted from the level shifter 10 shown in FIG. 6 is the same as the Dshift outputted from the level shifter 1 shown in FIG. 2 (see the timing charts shown in FIGS. 7 and 3).

The level shifter 10 shown in FIG. 6 can output the level shift data Dshift without an inverted input data Din_inv used for shifting a level of the input data Din. Further, the level shifter 10 comprises two transistors 2 and 3. The transistor 2 is controlled by the clock signal CLK, so that the transistor 2 is in the on-state during the data invalid periods. On the other hand, it is noted that the transistor 3 is controlled by the changed input data Din′ outputted from the AND circuit 5. The AND circuit 5 changes the voltages of the input data Din of the data invalid periods to 0V and then outputs the input data Din as the changed input data Din′, so that the transistor 3 is always in the off-state during the data invalid periods. Therefore, the transistor 3 is in the off-state while the transistor 2 is in the on-state, so that the power supply Vdd and the power supply Vss are prevented from becoming shorted to each other during the operation of the level shifter 10 and thus lower power consumption is achieved.

In the third embodiment, to provide the means for changing the input data Din (2.5V/0V), the AND circuit 5, realizes the level shifter 10 (see FIG. 6) in which the transistor 4 required for the level shifter 1 shown in FIG. 2 is omitted. This concept can be applied to the level shifter 11 shown in FIG. 4, so that to provide the means for changing the input data Din (1.5V/0V) can realize a different level shifter in which the transistor 12 required for the level shifter 11 is omitted.

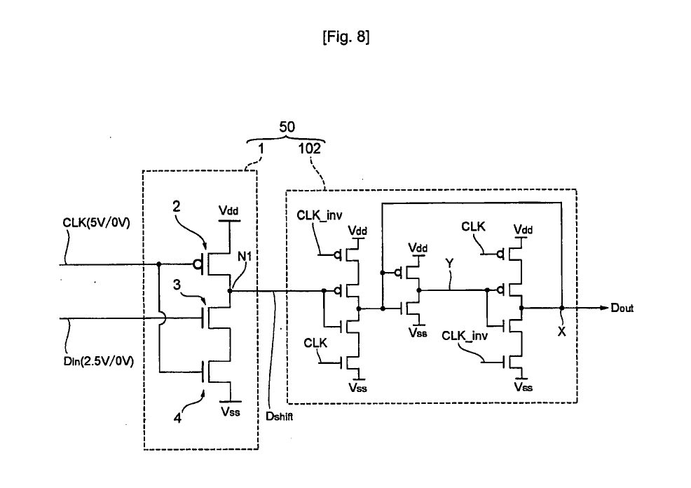

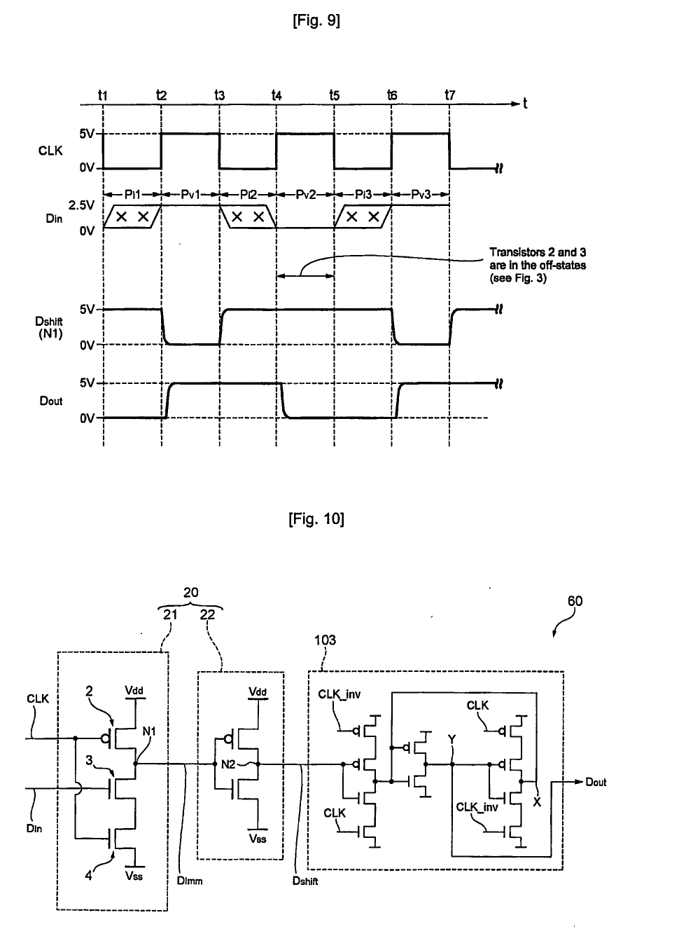

FIG. 8 is a schematic diagram showing a voltage converting device 50 in which the level shifter 1 shown in FIG. 2 is used. FIG. 9 shows a timing chart of the voltage converting device 50.

The voltage converting device 50 comprises the level shifter 1 shown in FIG. 2 and a latch 102. The latch 102 shown in FIG. 8 has the same structure as the latch 102 shown in FIG. 1 has.

The level shifter Dshift outputted from the level shifter 1 is processed by the latch 102 and is outputted as an output data Dout. An detailed explanation of an operation of the latch 102 is omitted since the latch 102 itself is known. If the voltage of the input data Din is 2.5V, this voltage of 2.5V is shifted to the voltage of 0V by the level shifter 1 as explained with respect to FIGS. 2 and 3, so that the voltage of the level shift data Dshift is 0V. The voltage of 0V of the level shift data Dshift is converted into a voltage of 5V by the latch 102, so that the output data Dout is 5V. On the other hand, if the voltage of the input data Din is 0V, this voltage of 0V is shifted to the voltage of 5V by the level shifter 1, so that the voltage of the level shift data Dshift is 5V. The voltage of 5V of the level shift data Dshift is converted into a voltage of 0V by the latch 102, so that the output data Dout is 0V. Therefore, the voltage converting device 50 outputs the voltage of 5V if the input data Din is 2.5V, but outputs the voltage of 0V if the input data Din is 0V.

It is noted that, in the voltage converting device 50 shown in FIG. 8, both transistors 2 and 3 of the level shifter 1 are in the off-state during the period of instant t4 to the instant t5 (see FIG. 3) and thus the node N1 is not connected to both the power supply Vdd and the power supply Vss. Therefore, if an input capacitance of the latch 102 is changed by a rising or a falling of the clock signal CLK or CLK_inv, the voltage on the node N1 (the level shift data Dshift) during the period from the instant t4 to the instant t5 may change with the change in this input capacitance. In this case, there is no problem if an amount of change in voltage is negligible. However, if the voltage on the node N1 is changed to an extent that the latch 102 incorrectly recognizes the voltage on the node N1 as 0V instead of 5V, the voltage converting device 50 can not output the correct output data Dout. For this reason, if the amount of change in voltage on the node N1 may not be negligible, the voltage converting device 50 shown in FIG. 8 can be configured, for example, as shown in FIG. 10.

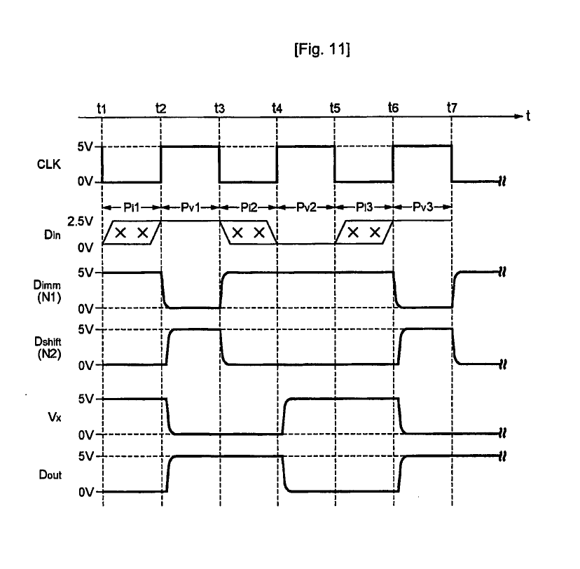

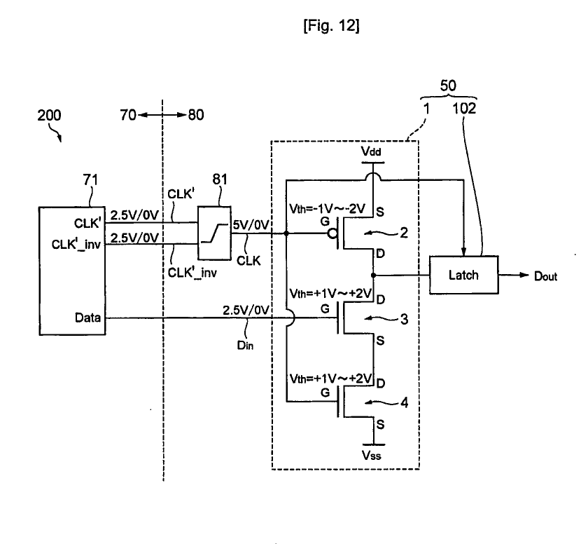

FIG. 10 is schematic diagram showing a voltage converting device 60 of a different example from the voltage converting device 50 shown in FIG. 8. FIG. 11 is a timing chart of the voltage converting device 60.

The voltage converting device 60 comprises a level shifter 20 and a latch 103. The level shifter 20 comprises a first portion 21. The first portion 21 has the same structure as the level shifter 1 shown in FIG. 8 has. Therefore, an intermediate shift data Dimm on the node N1 of the first portion 21 has the same waveform as the level shift data Dshift shown in FIG. 9 has. It is noted that the level shifter 20 shown in FIG. 10 comprises a second portion 22 in a succeeding stage of the first portion 21. Therefore, the intermediate shift data Dimm outputted from the first portion 21 is not supplied to the latch 103, but supplied to the second portion 22. Since the second portion 22 is an inverter, the intermediate shift data Dimm is inverted by the second portion 22 and the inverted intermediate shift data Dimm appears on the node N2 of the second portion 22 as a level shift data Dshift.

Since the node N2 is connected to the power supply Vdd when the voltage of the intermediate shift data Dimm is 0V and the node N2 is connected to the power supply Vss when the voltage of the intermediate shift data Dimm is 5V, it is noted that the node N2 is substantially always connected to the power supply Vdd or the power supply Vss. Therefore, even if the voltage on the node N2 changes because of the change in the input capacitance of the latch 103, the changed voltage on the node N2 can be immediately returned to the original voltage. As a result, the level shift data Dshift outputted from the level shifter 20 is received by the latch 103 without being substantially affected by the change in the input capacitance of the latch 103.

It is noted that a relationship between the level shift data Dshift received by the latch 103 shown in FIG. 10 and the level shift data Dshift received by the latch 102 shown in FIG. 8 is an inverted relationship (see the timing charts of FIGS. 9 and 11). Therefore, assuming that a voltage on a node X is taken from the latch 103 shown in FIG. 10 as the output data Dout in the same manner as the latch 102 shown in FIG. 8 carries out, the output data Dout of the voltage converting device 60 shown in FIG. 10 is represented by inverting the output data Dout of the voltage converting device 50 shown in FIG. 8. In order that the voltage converting device 60 shown in FIG. 10 can output the substantially same output data Dout as the voltage converting device 50 shown in FIG. 8 outputs, the voltage converting device 60 outputs a voltage on a node Y instead of the node X as the output data Dout. This makes it possible that the voltage converting device 60 shown in FIG. 10 outputs the substantially same output data Dout as the voltage converting device 50 shown in FIG. 8 outputs although the level shifter 20 comprises the second portion 22 (inverter).

In FIGS. 8 to 11, the level shifter 1 shown in FIG. 2 is applied to the voltage converting device. However, even if the level shifter 10 shown in FIG. 6 is used instead of the level shifter 1, the same output data Dout as FIGS. 9 and 11 illustrate are outputted.

A voltage converting device can be obtained by combining the level shifter 11 shown in FIG. 4 and a latch.

FIG. 12 shows an example in which the voltage converting device 50 shown in FIG. 8 is applied to a mobile phone 200.

FIG. 12 schematically illustrates a part of a liquid crystal cell at a side of a glass substrate 80 and a part of a TCP 70, and the TCP 70 is attached to the glass substrate 80 with an anisotropic conductive film (not shown). On the glass substrate 80, the voltage converting device 50 shown in FIG. 8 is provided. On the TCP 70, an IC chip 71 is mounted. The IC chip 71 outputs a clock signal (hereinafter, referred to as “IC clock signal”) CLK′, an inverted clock signal (hereinafter, referred to as “inverted IC clock signal”) CLK′_inv, and digital data of 1 bit (Data). The voltage converting device 50 receives this Data outputted from the IC chip 71 as an input data Din and then outputs an output data Dout. It is noted that, for the purpose of controlling a transistor 2, the voltage converting device 50 dose not receive the IC clock signal CLK′ but receives a clock signal CLK obtained by shifting a level of the IC clock signal CLK′ with a level shifter 81. This reason will be described below.

Transistors used in the IC chip 71 is usually formed on a silicon substrate, but the transistors 2, 3, and 4 of the voltage converting device 50 are formed on the glass substrate 80. Therefore, the transistors 2, 3, and 4 formed on the glass substrate 80 are usually different in threshold voltage from the transistors used in the IC chip 71. As one example, p-type and n-type transistors used in the IC chip 71 has threshold voltage of approximately −1V and +1V, respectively, but the p-type transistor 2 formed on the glass substrate 80 has a threshold voltage of −1V to −2V and the n-type transistors 3 and 4 formed on the glass substrate 80 have a threshold voltage of +1V to +2V. For this reason, power supply voltages Vss and Vdd required for the voltage concerting device 50 are different from those required for the IC chip 71 (for example, the voltage Vdd required for the voltage converting device 50 must be higher than the voltage Vdd required for the IC chip 71). As one example, the power supply voltages Vss and Vdd required for the IC chip 71 is 0V and 2.5V, respectively, but the power supply voltages Vss and Vdd required for the voltage converting device 50 is 0V and 5V, respectively. In the case that the power supply voltages of the IC chip 71 are Vss=0V and Vdd=2.5V, the IC clock signal CLK′ has the voltages of 0V and 2.5V, whereas in the case that the power supply voltages of the voltage converting device 50 are Vss=0V and Vdd=5V, the source S of the transistor 2 is connected to power supply Vdd (=5V). Under such situation, if the IC clock signal CLK′ itself is applied to the gate G of the transistor 2 of the level shifter 1, the V_{GS} of the transistor 2 becomes −2.5V or −5V. Therefore, if the threshold voltage Vth of the transistor 2 is −1V to −2V, the V_{GS} of the transistor 2 dose not exceed the threshold voltage Vth, so that the transistor 2 can be turned on but can not be turned off. In order to ensure ON and OFF of the transistor 2, a different clock signal from the IC clock signal CLK′ can be applied to the gate G of the transistor 2, for example. This different clock signal may be, for example, a clock signal having a low level voltage of 0V and a high level voltage of 5V. If the clock signal having the voltages of 0V and 5V, the V of the transistor 2 becomes 0V and −5V, so that the transistor 2 can be reliably turned on and off even if the transistor 2 has the threshold voltage of −1V to −2V. In order to generate such different clock signal, the level shifter 81 for shifting the voltage level of the IC clock signal CLK′ is provided in FIG. 12. The level shifter 81 may be, for example, the level shifter 101 shown in FIG. 1. By supplying the level shifter 101 shown in FIG. 1 with the IC clock signal CLK′ and the inverted IC clock signal CLK′_inv instead of the input data Din and the inverted input data Din_inv, the level shifter 101 outputs the clock signal CLK having the voltages of 0V and 5V. Therefore, the transistor 2 can be surely turned on and off by supplying the clock signal CLK to the transistor 2 of the level shifter 1.

In this way, the voltage converting device 50 can convert the input data Din received from the IC chip 71 into the desired output data Dout as shown in the timing chart of FIG. 9.

In FIG. 12, in order to be able to shift the voltage level of the digital data of 1 bit Data outputted from the IC chip 71, one voltage converting device 50 shown in FIG. 8 is provided. If it is necessary that the IC chip 71 outputs digital data of a plurality of bits and that voltage levels of the digital data of the plurality of bits are shifted, a plurality of voltage converting devices each of which is the voltage converting device shown in FIG. 8 may be accordingly provided. A case in which the plurality of voltage converting devices are provided and each of the voltage converting devices is the voltage converting devices shown in FIG. 8 will be described below.

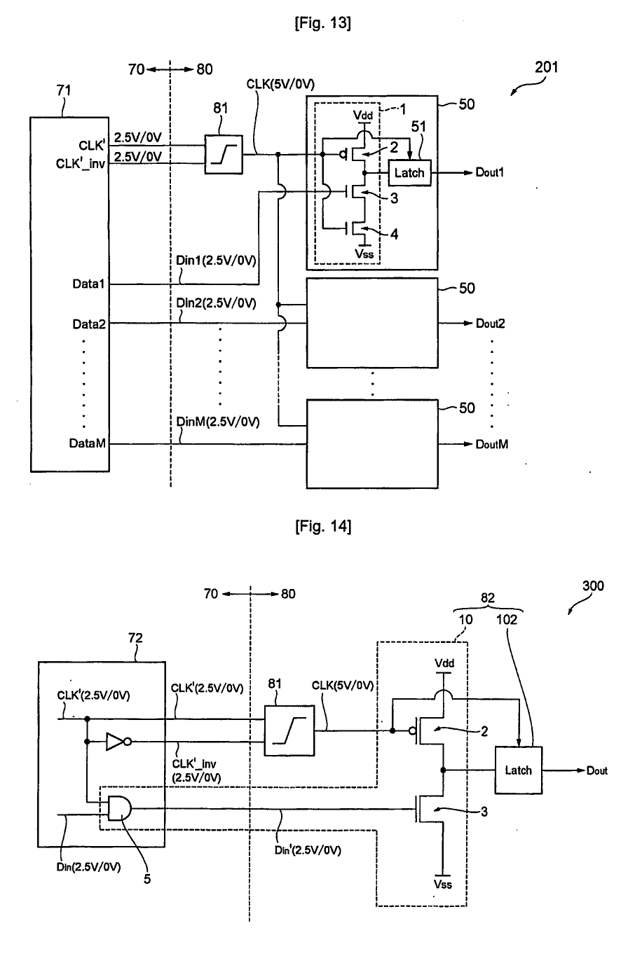

FIG. 13 shows an example in which a mobile phone 201 comprises a plurality of voltage converting devices 50 and each of the voltage converting devices 50 is the voltage converting device 50 shown in FIG. 8.

An IC chip 71 mounted on a TCP 70 outputs M digital data Data1, Data2, . . . , DataM. In order to shift the voltage levels of the M digital data Data1, Data2, . . . , DataM, M voltage converting devices 50 are formed on the glass substrate 80, and each of the voltage converting devices 50 is the voltage converting device shown in FIG. 8. Each of M digital data Data1, Data2, . . . , DataM outputted from the IC chip 71 is supplied to a respective one of the voltage converting devices 50 as a respective one of input data Din1, Din2, . . . , DinM. The voltage converting devices 50 are supplied with the clock signal CLK (5V/0V) outputted from the level shifter 81 instead of the IC clock signal CLK′ (2.5V/0V) outputted from the IC chip 71 in order to surely control the transistor 2 of the level shifter 1 of each of the voltage converting devices 50.

In FIG. 13, each of M digital data Data1, Data2, . . . , DataM outputted from the IC chip 71 is received by a respective one of voltage converting devices 50, so that the voltage levels of M digital data are shifted and then the shifted M digital data are outputted as output data Dout 1, Dout 2, . . . , DoutM.

In FIG. 13, since each of the voltage converting devices 50 is provided with the level shifter 1 according to the present invention, the power supply Vdd and the power supply Vss are prevented from becoming shorted to each other, and thus low power consumption of the mobile phone 201 is achieved.

Now, assuming in FIG. 13 that the conventional level shifter 101 shown in FIG. 1 is used instead of each of the level shifters 1. In this case, it is noted that, in order for the level shifters 101 to shift the digital data Data1, Data2, . . . , DataM, each of the level shifters 101 must additionally receive a respective one of the inverted digital data Data1_inv, Data2_inv, . . . , DataM_inv. Therefore, in the case that the conventional level shifter 101 shown in FIG. 1 is used instead of each of the level shifters 1, the IC ship 71 must be provided with output portions of the inverted digital data Data1_inv, Data2_inv, . . . , DataM_inv in addition to the output portions of the digital data Data1, Data2, . . . , DataM. In contrast, in the case of the mobile phone 201 shown in FIG. 13, the clock signal CLK outputted from the level shifter 81 is commonly used for M level shifters 1 according to the present invention, so that the voltage levels of M input data Din m to DinM can be shifted using one clock signal CLK and can be shifted without using M inverted input data for the level shifters. Therefore, the IC chip 71 need not have M output portions for the inverted digital data Data1_inv, Data2_inv, . . . , DataM_inv corresponding to the M digital data Data1, Data2, . . . , DataM, so that an interface for connecting the IC chip 71 and the level shifters 1 is simplified.

FIG. 14 shows an example in which the level shifter 10 shown in FIG. 6 is applied to a mobile phone 300.

FIG. 14 schematically illustrates a part of a liquid crystal cell at a side of a glass substrate 80 and a part of a TCP 70, and the TCP 70 is attached to the glass substrate 80 with an anisotropic conductive film (not shown). On the glass substrate 80, the level shifter 10 shown in FIG. 6 and the latch 102 shown in FIG. 1 are provided. The voltage converting device 82 consists of the level shifter 10 and the latch 102. On the TCP 70, an IC chip 71 is mounted. Like the mobile phone 200 shown in FIG. 12, the mobile phone 300 comprises the level shifter 81 in order to control the transistor 2 of the level shifter 10.

The transistor 3 of the level shifter 10 is controlled by the changed input data Din′ outputted from the AND circuit 5. Since the voltage levels of the changed input data Din′ is 0V and 2.5V (see FIG. 6), the changed input data Din′ is generated in the IC chip 72 which operates with the power supply of 2.5V. Therefore, the AND circuit 5 is formed within the IC chip 72. The AND circuit 5 receives the input data Din and the IC clock signal CLK′ and outputs the changed input data Din′ having the voltage levels of 0V and 2.5V (see the timing chart of FIG. 7).

In this way, the p-type transistor 2 is controlled by the clock signal CLK having the voltage levels of 0V and 5V, and the n-type transistor 3 is controlled by the changed input data Din′ having the voltage levels of 0V and 2.5V. Therefore, the level shifter 10 can convert the input data Din into the desired output data Dout as shown in the timing chart of FIG. 7.

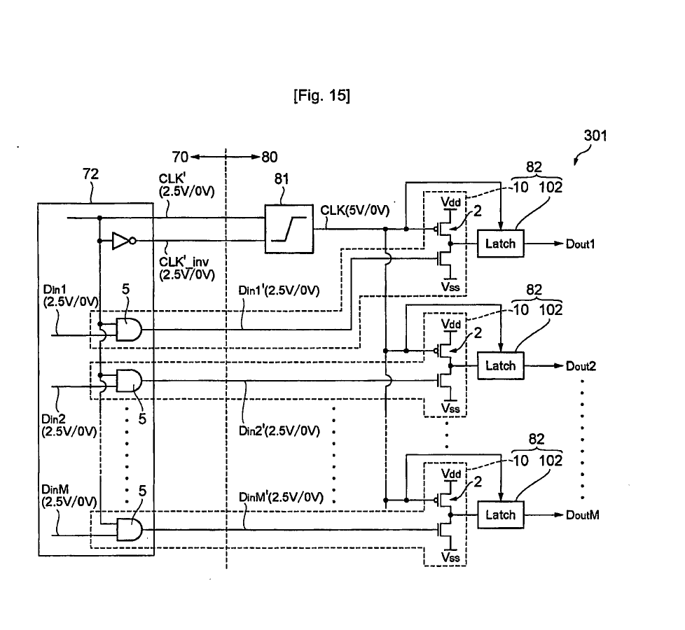

FIG. 15 shows an example in which a mobile phone 301 comprises a plurality of voltage converting devices and each of the voltage converting devices is the voltage converting device 82 shown in FIG. 14.

In order to convert M digital data Din1, Din 2, . . . , DinM, the IC chip 72 mounted on the TCP 70 comprises M voltage converting devices 82 each of which is the voltage converting device 82 shown in FIG. 14. In order to surely control the transistor 2 of each of the level shifters 10, each of the voltage converting devices 82 is supplied with the clock signal CLK having the voltage levels of 0V and 5V from the level shifter 81. Since each of the input data Din1′, Din 2′, . . . , DinM outputted from the AND circuits 5 of the voltage converting devices 82 has the voltage levels of 0V and 2.5V, the AND circuit 5 of each of the voltage converting devices 82 is formed within the IC chip 72.

Since the mobile phone 301 comprises the level shifters 10 according to the invention, the power supply Vdd and the power supply Vss are prevented from becoming shorted to each other during the operation of the level shifter 10, so that the lower power consumption of the mobile phone 301 is achieved.

In the mobile phone 301 shown in FIG. 15, two clock signals CLK′ and CLK are inputted into each of M level shifters 10, and thus two clock signals CLK′ and CLK are commonly used for M level shifters 10. Therefore, the voltage levels of M input data Din1 to DinM can be shifted using two clock signals CLK′ and CLK and can be shifted without using M inverted input data for the level shifters. As a result, the IC chip 72 need not have M output portions for M inverted digital data Din1_inv, Din2_inv, . . . , DinM_inv corresponding to M input data Din1, Din 2, . . . , DinM, so that an interface for connecting the IC chip 72 to the level shifters 10 is simplified.

Although the level shifters 1 and 10 shown in FIGS. 2 and 6 are used in the mobile phones 200, 201, 300, and 301 described above, the level shifter 11 shown in FIG. 4 can be applied to a mobile phone. Further, although the examples in which these level shifters are applied to the mobile phones are described above, the level shifter according to the invention can be applied to the other devices in which voltage levels are required to be shifted.

Although the level shifters described above receive the input data having two voltage levels (0V and 5V) and then shift two voltage levels, it is also possible that, according to the invention, a level shifter is structured so as to receive input data having one voltage level or three or more voltage levels and then shift the received one voltage level or three or more voltage levels.

1. A level shifter for receiving a first clock signal and data having a first voltage to shift said first voltage to a second voltage, said level shifter comprising:
a first voltage supplying means for supplying said second voltage to a predetermined position and
a second voltage supplying means for supplying a third voltage to said predetermined position, wherein said second voltage supplying means operates so as to block supply of said third voltage to said predetermined position when said first voltage supplying means supplies said second voltage to said predetermined position.

2. A level shifter as claimed in claim 1, wherein during a first period, said first voltage supplying means supplies said second voltage to said predetermined position and said second voltage supplying means blocks supply of said third voltage to said predetermined position, and wherein during a second period succeeding to said first period, said first voltage supplying means blocks supply of said second voltage to said predetermined position and said second voltage supplying means continues to block supply of said third voltage to said predetermined position.

3. A level shifter as claimed in claim 2, wherein during said first period, said first voltage supplying means supplies said second voltage to said predetermined position in response to said first clock signal and said second voltage supplying means blocks supply of said third voltage to said predetermined position in response to said first clock signal and said data, and wherein during said second period, said first voltage supplying means blocks supply of said second voltage to said predetermined position in response to said first clock signal and said second voltage supplying means continues to block supply of said third voltage to said predetermined position in response to said first clock signal and said data.

4. A level shifter as claimed in claim 1, wherein during a first period, said first voltage supplying means blocks supply of said second voltage to said predetermined position and said second voltage supplying means supplies said third voltage to said predetermined position, and wherein during a second period succeeding to said first period, said first voltage supplying means supplies said second voltage to said predetermined position and said second voltage supplying means blocks supply of said third voltage to said predetermined position.

5. A level shifter as claimed in claim 4, wherein during said first period, said first voltage supplying means blocks supply of said second voltage to said predetermined position in response to said first clock signal and said second voltage supplying means supplies said third voltage to said predetermined position in response to said first clock signal and said data, and wherein during a second period succeeding to said first period, said first voltage supplying means supplies said second voltage to said predetermined position in response to said first clock signal and said second voltage supplying means blocks supply of said third voltage to said predetermined position in response to said first clock signal and said data.

6. A level shifter as claimed in any one of claim 2, wherein said first voltage supplying means comprises a first switch means, said first switch means becoming on-state and off-state in response to said first clock signal, wherein said second voltage supplying means comprises a second switch means, said second switch means becoming on-state and off-state in response to said first clock signal, and wherein said second switch means is off-state when said first switch means is on-state, and said second switch means is on-state when said first switch means is off-state.

7. A level shifter as claimed in claim 6, wherein said level shifter comprises a third switch means between said predetermined position and said second switch means, said third switch means becoming on-state and off-state in response to said data.

8. A level shifter as claimed in claim 2 wherein said first voltage supplying means comprises a fourth switch means, said fourth switch means becoming on-state and off-state in response to said first clock signal, wherein said second voltage supplying means comprises a data processing means for processing said data and a fifth switch means, said fifth switch means becoming on-state and off-state in response to said processed data, and wherein said fifth switch means is in off-state when said fourth switch means is in on-state, and said fifth switch means is in on-state when said fourth switch means is in off-state.

9. A level shifter as claimed in claim 8, wherein said data has a data valid period and a data invalid period, and wherein said data processing means changes a voltage of said data of said data in valid period to a voltage used for making said fifth switch means on-state or off-state.

10. A level shifter as claimed in claim 9, wherein said data processing means changes a voltage of said data of said data in valid period to a voltage used for making said fifth switch means on-state or off-state by using second clock signal, said second clock signal having voltage levels in versed with respect to voltage levels of said first clock signal.

11. A voltage converting device comprising said level shifter as claimed in any one of claim 1.
